(19) United States
(12) Patent Application Publication
(10) Pub. No.: US 2005/0054164 A1
(43) Pub. Date: Mar. 10, 2005

(54) Strained silicon MOSFETs having reduced diffusion of n-type dopants

(75) Inventor: Qi Xiang, San Jose, CA (US)

Correspondence Address: FOLEY & LARDNER, 2029 CENTURY PARK EAST, SUITE 3500, LOS ANGELES, CA, 90067, US

(73) Assignee: Advanced Micro Devices, Inc.

(21) Appl. No.: 10/658,611

(22) Filed: Sep. 9, 2003

(51) Int. Cl. H01L 21/336

(52) U.S. Cl. 438/285; 438/305

(57) ABSTRACT

Processing is performed during fabrication of a strained silicon NMOS device to create point defects in silicon germanium portions of source regions, and optionally of drain regions, prior to activation of source and drain region dopants. The point defects retard diffusion of the n-type dopants in the silicon germanium material, effectively lengthening the duration of the diffusivity transient region and resulting in lower overall dopant diffusivity during activation.

### BACKGROUND OF THE INVENTION

1. Field of the Invention

The present invention relates generally to fabrication of metal oxide semiconductor field effect transistors (MOSFETs), and, more particularly, to MOSFETs that achieve improved carrier mobility through the incorporation of strained silicon.

2. Related Technology

MOSFETs are a common component of integrated circuits (ICs). FIG. 1 shows a cross sectional view of a conventional MOSFET device. The MOSFET is fabricated on a silicon substrate 10 within an active region bounded by shallow trench isolations 12 that electrically isolate the active region of the MOSFET from other IC components fabricated on the substrate 10.

The MOSFET is comprised of a gate 14 and a channel region 16 that are separated by a thin gate insulator 18 such as silicon oxide or silicon oxynitride. A voltage applied to the gate 14 controls the creation of an inversion layer that provides carriers for conduction in the channel region 16 between the source and drain. To minimize the resistance of the gate 14, the gate 14 is typically formed of a doped semiconductor material such as polysilicon.

The source and drain of the MOSFET comprise deep source and drain regions 20 formed on opposing sides of the channel region 16. The deep source and drain regions 20 are formed by ion implantation subsequent to the formation of a spacer 22 around the gate 14. The spacer 22 serves as a mask during implantation to define the lateral positions of the deep source and drain regions 20 relative to the channel region 16.

The source and drain of the MOSFET further comprise shallow source and drain extensions 24. As dimensions of the MOSFET are reduced, short channel effects resulting from the small distance between the source and drain cause degradation of MOSFET performance. The use of shallow source and drain extensions 24 rather than deep source and drain regions near the ends of the channel 16 helps to reduce short channel effects. The shallow source and drain extensions 24 are implanted after the formation of a protective layer 26 around the gate 14 and over the substrate, and prior to the formation of the spacer 22. The gate 14 and the protective layer 26 act as an implantation mask to define the lateral position of the shallow source and drain extensions 24 relative to the channel region 16. Diffusion during subsequent annealing causes the shallow source and drain extensions 24 to extend slightly beneath the gate 14.

Source and drain suicides 28 are formed on the deep source and drain regions 20 to provide ohmic contacts and reduce contact resistance. The silicides 28 are comprised of the substrate semiconductor material and a metal such as cobalt (Co) or nickel (Ni). The deep source and drain regions 20 are formed deeply enough to extend beyond the depth to which the source and drain suicides 28 are formed. The gate 14 likewise has a silicide 30 formed on its upper surface. A gate structure comprising a polysilicon material and an overlying silicide as shown in FIG. 1 is sometimes referred to as a polycide gate.

One option for increasing the performance of MOSFETs is to enhance the carrier mobility of the MOSFET semiconductor material so as to reduce resistance and power consumption and to increase drive current, frequency response and operating speed. A method of enhancing carrier mobility that has become a focus of recent attention is the use of silicon material to which a tensile strain is applied. “Strained” silicon may be formed by growing a layer of silicon on a silicon germanium substrate. The silicon germanium lattice is more widely spaced on average than a pure silicon lattice because of the presence of the larger germanium atoms in the lattice. Since the atoms of the silicon lattice align with the more widely spaced silicon germanium lattice, a tensile strain is created in the silicon layer. The silicon atoms are essentially pulled apart from one another. The amount of tensile strain applied to the silicon lattice increases with the proportion of germanium in the silicon germanium lattice.

The tensile strain applied to the silicon lattice increases carrier mobility. Relaxed silicon has six equal valence bands. The application of tensile strain to the silicon lattice causes four of the valence bands to increase in energy and two of the valence bands to decrease in energy. As a result of quantum effects, electrons effectively weigh 30 percent less when passing through the lower energy bands. Thus the lower energy bands offer less resistance to electron flow. In addition, electrons encounter less vibrational energy from the nucleus of the silicon atom, which causes them to scatter at a rate of 500 to 1000 times less than in relaxed silicon. As a result, carrier mobility is dramatically increased in strained silicon as compared to relaxed silicon, offering a potential increase in mobility of 80% or more for electrons and 20% or more for holes. The increase in mobility has been found to persist for current fields of up to 1.5 megavolts/centimeter. These factors are believed to enable a device speed increase of 35% without further reduction of device size, or a 25% reduction in power consumption without a reduction in performance.

An example of a MOSFET incorporating a strained silicon layer is shown in FIG. 2. The MOSFET is fabricated on a substrate comprising a silicon germanium layer 32 grown on a silicon layer 10. An epitaxial layer of strained silicon 34 is grown on the silicon germanium layer 32. The MOSFET uses conventional MOSFET structures including deep source and drain regions 20, shallow source and drain extensions 24, a gate oxide layer 18, a gate 14 surrounded by a protective layer 26, a spacer 22, source and drain silicides 28, a gate silicide 30, and shallow trench isolations 12. The channel region of the MOSFET includes the strained silicon material, which provides enhanced carrier mobility between the source and drain.

An alternative to the formation of devices on semiconductor substrates is silicon on insulator (SOI) construction. In SOI construction, MOSFETs are formed on a substrate that includes a layer of a dielectric material beneath the MOSFET active regions. SOI devices have a number of advantages over devices formed in a semiconductor substrate, such as better isolation between devices, reduced leakage current, reduced latch-up between CMOS elements, reduced chip capacitance, and reduction or elimination of short channel coupling between source and drain regions.

FIG. 3 shows an example of a strained silicon MOSFET formed on an SOI substrate. In this example, the MOSFET is formed on an SOI substrate that comprises a silicon germanium layer 32 provided on a dielectric layer 36. The MOSFET is formed within an active region defined by trench isolations 12 that extend through the silicon germanium layer 32 to the underlying dielectric layer 36. The SOI substrate may be formed by a buried oxide (BOX) method or by a wafer bonding method. In one alternative to the construction shown in FIG. 3, strained silicon FinFETs comprised of monolithic silicon germanium FinFET bodies having strained silicon grown thereon may be patterned from the silicon germanium layer of the SOI substrate.

One problem with strained silicon devices as shown in FIGS. 2 and 3 is that n-type dopants such as arsenic (As) and phosphorous (P) that are used in the source and drain regions of p-channel devices have a much higher diffusivity in silicon germanium than in silicon. Experiments have demonstrated that at temperatures in the range of 950-1050 degrees C., the effective diffusivity of phosphorus in silicon germanium is approximately double than in silicon, while the effective diffusivity of arsenic in silicon germanium is approximately seven or more times greater than in silicon. As a result, high temperature processing such as annealing to activate source and drain dopants causes significantly greater diffusion of the source and drain dopants in the silicon germanium regions of strained silicon NMOS devices than in conventional silicon NMOS devices. The enhanced diffusion effectively shortens the channel length in the silicon germanium layer and increases the risk of short channel effects such as punch-through.

Studies have shown that the diffusivity of n-type dopants in silicon germanium under the transient conditions that exist at the beginning of annealing is significantly less than the diffusivity exhibited once steady state conditions are established. FIG. 4 is a graph showing the diffusivity of arsenic in silicon and in silicon germanium during annealing of substrates having an arsenic concentration of approximately 5×10²⁰ cm⁻³ at a nominal annealing temperature of 1000 degrees C. It is seen that arsenic exhibits Transient Enhanced Diffusion (TED) in silicon, in that diffusivity is initially high in the transient region and becomes lower as a steady state is established. In contrast, arsenic exhibits Transient Retarded Diffusion (TRD) in silicon germanium, in that diffusivity is initially low in the transient region and becomes higher as a steady state is reached. Similar results have been found for phosphorous diffusivity. As a general matter, the length of the transient region is dependent on a number of parameters including the annealing technique, the annealing temperature, and the dopant concentration. While it would be desirable to constrain anneal times for silicon germanium substrates to within the transient region so as to reduce dopant diffusion during activation, the optimal portion of the transient region illustrated in FIG. 4 is less than five seconds in length, whereas conventional rapid thermal annealing (RTA) typically requires in excess of sixty seconds. As a result, most of the annealing process takes place outside of the transient region and therefore the retarded diffusion of the transient region has relatively little influence on overall dopant diffusion.

It would therefore be desirable for the transient region of n-type dopant diffusivity in silicon germanium to be longer in order to reduce diffusion during annealing.

### SUMMARY OF THE INVENTION

It has been determined that the mechanism that governs the transient retarded diffusivity of n-type dopants in silicon germanium is influenced by the density of point defects in the silicon germanium lattice. In particular, an increased point defect density correlates with lower n-type dopant diffusivity in the transient region. Therefore, in accordance with embodiments of the invention, processing is performed during NMOS fabrication to enhance transient effects by creating point defects in the silicon germanium portions of source regions, and optionally in the silicon germanium portions of drain regions, prior to activation of dopants, resulting in a lower overall dopant diffusivity during activation.

In accordance with one embodiment of the invention, a MOSFET is characterized by the formation during processing of an intermediate structure in which, prior to activation of n-type source and drain dopants, at least the source region contains a greater number of point defects than those formed by implantation of the n-type dopant itself.

In accordance with another embodiment of the invention, a semiconductor device is formed that has reduced overall n-type dopant diffusivity during activation. Initially a substrate is provided. The substrate includes a layer of silicon germanium on which is formed a layer of strained silicon. Point defects are then created in the silicon germanium layer in an NMOS device source region by implantation of a species such as silicon, germanium, or an inert element. The point defects extend the duration of a transient region of n-type dopant diffusivity in the silicon germanium of the source region. N-type dopant is then implanted into the silicon germanium layer at source and drain regions of the NMOS device, and annealing is performed to activate the n-type dopant in the source and drain regions. The point defects retard n-type dopant diffusion during activation.

In accordance with a further embodiment of the invention, an NMOS device is formed by forming a structure comprising n-type source and drain regions implanted in a silicon germanium layer of a substrate, wherein the silicon germanium of at least the source region contains point defects created by implantation of a species other than an n-type dopant. Annealing is then performed to activate the source and drain regions. The point defects retard n-type dopant diffusion during activation.

### DESCRIPTION OF THE DRAWINGS

Embodiments of the invention are described in conjunction with the following drawings, in which:

FIG. 1 shows a conventional MOSFET formed in accordance with conventional processing;

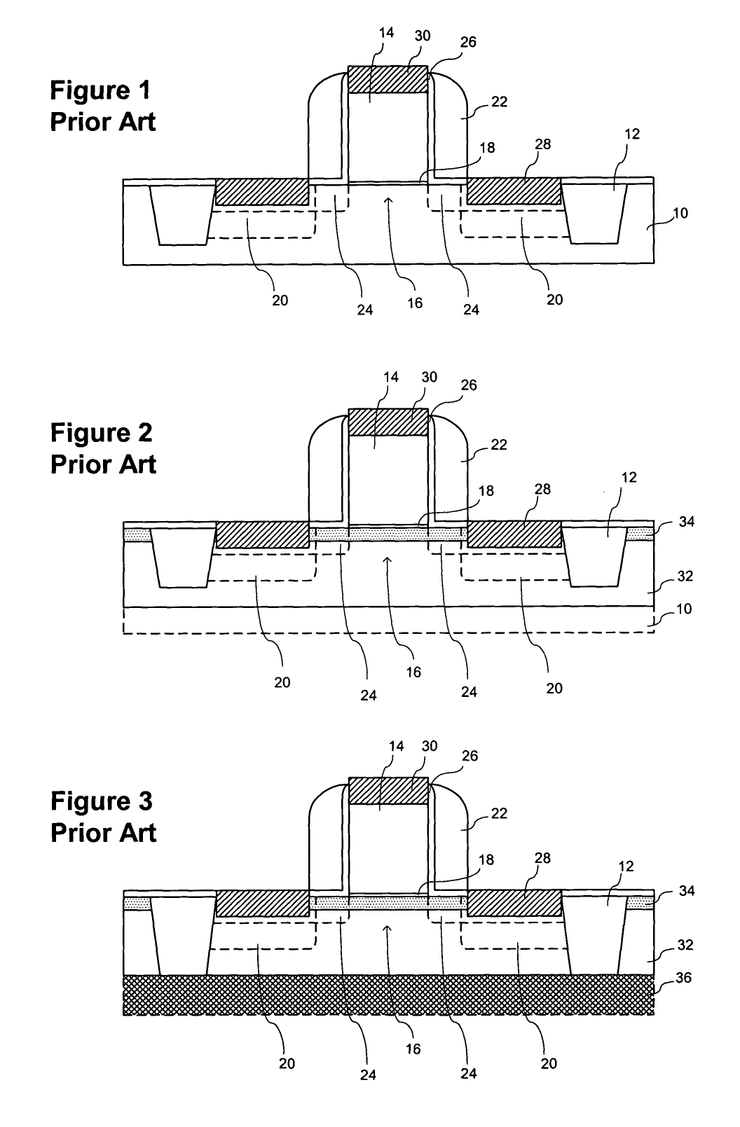

FIG. 2 shows a strained silicon MOSFET device;

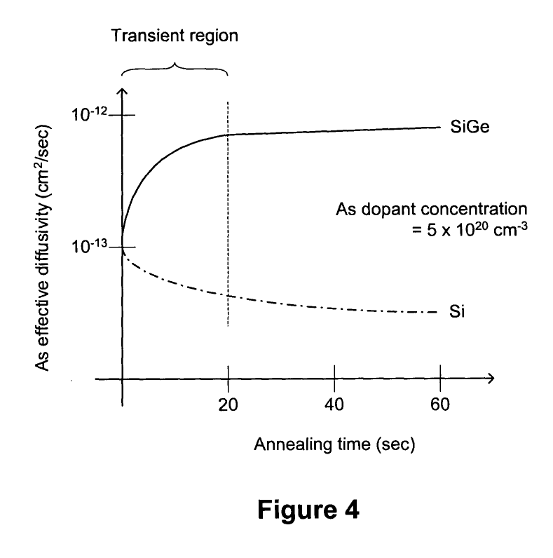

FIG. 3 shows a strained silicon MOSFET device formed on an SOI substrate;

FIG. 4 shows transient region diffusivity of arsenic in silicon and silicon germanium;

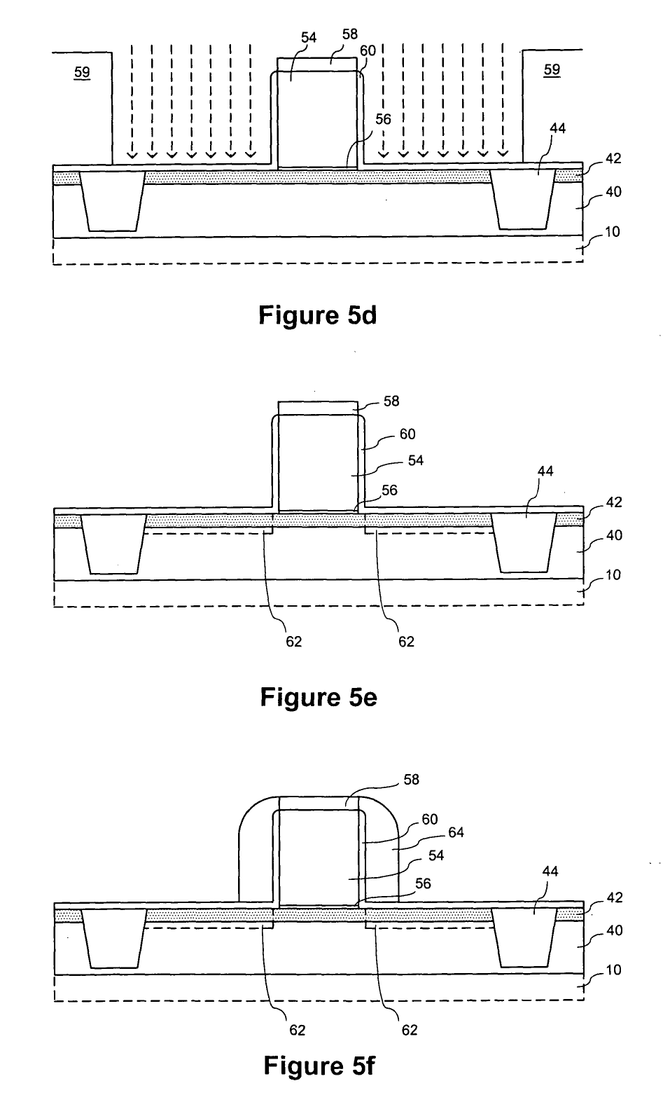

FIGS. 5a, 5b, 5c, 5d, 5e, 5f, 5g, 5h and 5i show structures formed during production of a MOSFET device in accordance with a preferred embodiment of the invention; and

FIG. 6 shows a process flow encompassing the preferred embodiment and alternative embodiments.

### DETAILED DESCRIPTION OF PREFERRED EMBODIMENTS

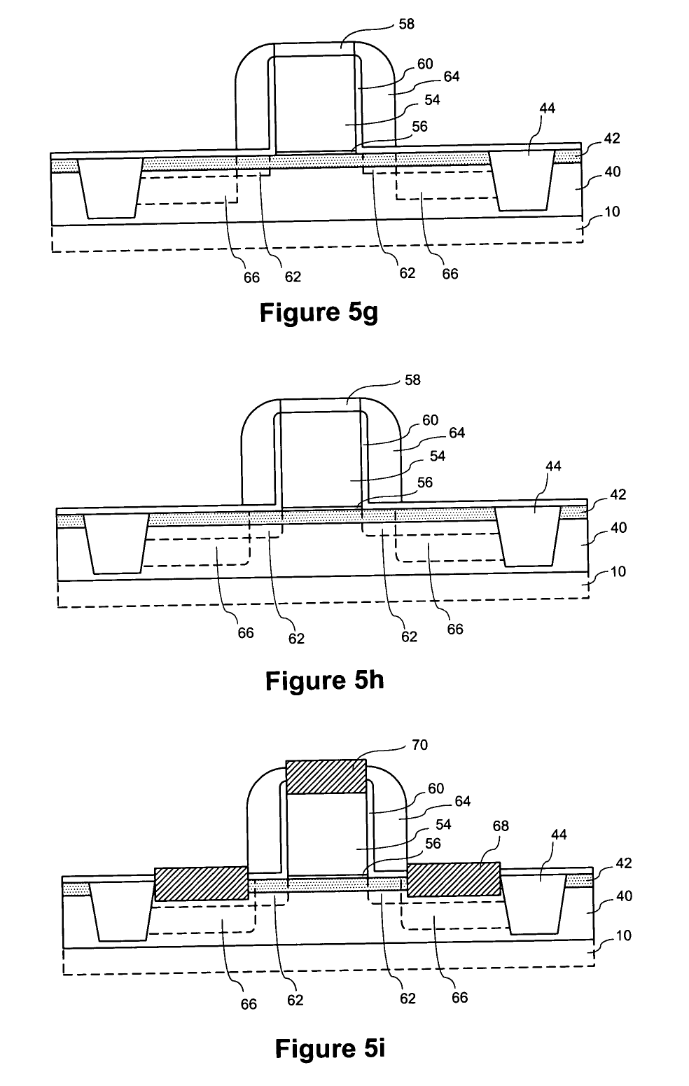

FIGS. 5a-5i show structures formed during fabrication of a strained silicon NMOS in accordance with preferred embodiments of the invention. FIG. 5a shows a structure comprising a silicon substrate 10 having grown thereon a silicon germanium layer 40 and a strained silicon layer 42. The silicon germanium layer 40 preferably has a composition Si₁₋ₓGeₓ, where x is approximately 0.2, and is more generally in the range of 0.1 to 0.3. Silicon germanium may be grown, for example, by chemical vapor deposition using Si₂H₆ (disilane) and GeH₄ (germane) as source gases, with a substrate temperature of 600 to 900 degrees C., a Si₂H₆ partial pressure of 30 mPa, and a GeH₄ partial pressure of 60 mPa. SiH₄ (silane) may be used as a source of silicon in alternative processes. The upper portion of the silicon germanium layer 40 should have a uniform composition.

The strained silicon layer 42 is preferably grown by chemical vapor deposition using Si₂H₆ as a source gas with a partial pressure of 30 mPa and a substrate temperature of approximately 600 to 900 degrees C. The strained silicon layer is preferably grown to a thickness of 200 Angstroms. The maximum thickness of strained silicon that can be grown without misfit dislocations will depend on the percentage of germanium in the silicon germanium layer 40. The silicon germanium layer 40 and the strained silicon layer 42 are preferably grown in situ in a single continuous deposition process.

The substrate shown in FIG. 5a further comprises shallow trench isolations 44 formed in the silicon germanium layer 40 and strained silicon layer 42. The shallow trench isolations 44 define an active region of the substrate in which a MOSFET will be formed. The shallow trench isolations 44 may be formed by forming trenches in the silicon germanium layer 40 and strained silicon layer 42, performing a brief thermal oxidation of the silicon germanium and strained silicon, and then depositing a layer of silicon oxide to a thickness that is sufficient to fill the trenches, such as by low pressure CVD (LPCVD) TEOS or atmospheric pressure ozone TEOS. The silicon oxide layer is then densified and planarized such as by chemical mechanical polishing or an etch back process. In accordance with one preferred alternative, the shallow trench isolations are comprised of an oxide trench liner and a silicon carbide bulk fill material. In another alternative, it may be preferred to form the shallow trench isolations 44 prior to growth of the strained silicon layer 42 to avoid creation of misfit dislocations in the strained silicon layer 42 as a result of the high temperatures used during formation of the shallow trench isolations.

FIG. 5b shows the structure of FIG. 5a after formation of multiple layers of material over the strained silicon layer 42 and the shallow trench isolations 44. A thin gate insulating layer 46 is formed on the strained silicon layer 42. The gate insulating layer 46 is typically silicon oxide but may be another material such as silicon oxynitride. Silicon oxide may be grown by thermal oxidation of the strained silicon layer 42 or may be deposited by chemical vapor deposition. Formed over the gate insulating layer 46 is a gate conductive layer 48. The gate conductive layer 48 typically comprises polysilicon that is heavily doped with an n-type dopant such as arsenic or boron. In some instances the polysilicon may also be implanted with germanium to enhance carrier mobility. Overlying the gate conductive layer 48 is a bi-layer hardmask structure comprising a lower hardmask layer 50, also referred to as a bottom antireflective coating (BARC), and an upper hardmask layer 52. The lower hardmask layer 50 is typically silicon oxynitride and the upper hardmask layer 52 is typically silicon nitride (e.g. Si₃N₄). The thicknesses of the layers are chosen to provide the desired antireflective properties.

FIG. 5c shows the structure of FIG. 5b after patterning of the gate conductive layer to form a gate 54. Patterning of the gate conductive layer typically removes at least a portion of any unprotected gate insulator layer material, leaving a gate insulator 56 beneath the gate 54. Patterning is performed using a series of anisotropic etches that patterns the upper hardmask layer using a photoresist mask as an etch mask, then patterns the lower hardmask layer using the patterned upper hardmask layer as an etch mask, then patterns the polysilicon using the patterned lower hardmask layer as an etch mask. A protective cap 58 formed from the silicon oxynitride BARC layer may be left on the gate 54.

FIG. 5d shows the structure of FIG. 5c after formation of a protective silicon oxide layer 60 on the strained silicon layer 42 and the exposed sidewalls of the gate 54. The protective layer 60 may be formed by thermal oxidation of the gate 54 and strained silicon 42.

As further shown in FIG. 5d, formation of the protective oxide layer 60 is followed by application of a photoresist mask 61 that selectively exposes active regions in which NMOS devices are to be formed while protecting active regions in which PMOS devices are to be formed, followed by implantation of an ion species to create point defects in the silicon germanium layer 40 at opposing sides of the gate 54 where source and drain regions will be formed. The protective cap 58 protects the gate 54 during creation of point defects.

The species that is implanted to create point defects may be silicon or germanium, or an inert element such as argon or xenon. The implantation dose depends on the particular species, with heavier species creating more point defects and therefore requiring a lower dose. As a general matter, the dose is preferably constrained so as to prevent the silicon germanium lattice from being amorphosized.

FIG. 5e shows the structure of FIG. 5d after implantation of n-type dopant such as arsenic or phosphorous by ion implantation to form shallow source and drain extensions 62 in the strained silicon layer 42 and silicon germanium layer 40 at opposing sides of the gate 54. Halo regions (not shown) may be implanted prior to implantation of the shallow source and drain extensions 62. Halo regions are regions that are implanted with a dopant that has a conductivity type that is opposite to that of the source and drain region dopants. The dopant of the halo regions retards diffusion of the dopant of the source and drain extensions. Halo regions are preferably implanted using a low energy at an angle to the surface of the substrate so that the halo regions extend beneath the gate 54 to beyond the anticipated locations of the ends of the source and drain extensions 62 after annealing.

FIG. 5f shows the structure of FIG. 5e after formation of a spacer 64 around the gate 54. The spacer 64 is preferably formed of silicon oxide. The spacer 64 may be formed by depositing a conformal layer of silicon oxide, followed by an etch back process to remove the silicon oxide from the substrate, leaving silicon oxide on the sidewalls of the gate as the spacer 64.

FIG. 5g shows the structure of FIG. 5f after implantation of n-type dopant such as arsenic or phosphorous to form deep source and drain regions 66 in the strained silicon 42 and silicon germanium 40 layers at opposing sides of the gate 54 by implantation of dopant. The spacer 64 serves as a mask during implantation of the deep source and drain regions 66 to define the lateral positions of the source and drain regions 66 relative to the gate 54.

FIG. 5h shows the structure of FIG. 5g after performing an annealing process to anneal the silicon germanium layer 40 and strained silicon layer 42 and to activate the dopants implanted in the shallow source and drain extensions 62 and the deep source and drain regions 66. The annealing process is preferably a “spike” anneal such as laser thermal annealing (LTA) that produces a rapid temperature increase. During annealing the implanted dopant undergoes diffusion, causing expansion of the respective regions. The duration of the anneal is preferably constrained so as to be equal to or less than the duration of the transient region during which the diffusion of n-type dopant within the silicon germanium layer 40 is retarded by point defects. The presence of the point defects caused by the implantation shown in FIG. 5d extends the duration of the transient region, resulting in lower overall diffusivity during annealing. If necessary, multiple anneals having durations less than the transient region may be performed.

FIG. 5i shows the structure of FIG. 5h after formation of source and drain suicides 68 and a gate suicide 70. The suicides 68, 70 are formed of a compound comprising a semiconductor material and a metal. Typically a metal such as cobalt (Co) is used, however other metals such as nickel (Ni) may also be employed. The silicides are formed by depositing a thin conformal layer of the metal over the entire structure, and then annealing to promote silicide formation at the points of contact between the metal and underlying semiconductor materials, followed by stripping of residual metal. Formation of suicides is typically preceded by a patterning step to remove oxides and protective layers from portions of the gate and the source and drain regions where the silicides are to be formed.

While the processing of FIGS. 5a-5i represents a preferred embodiment of the invention, a variety of alternatives may be implemented. In accordance with one alternative, only the source region of the NMOS device is subjected to point defect creation, while the NMOS drain region and any PMOS source and drain regions are protected by selective masking. Since the short channel effect is primarily controlled by the source region, reduction of the short channel effects caused by n-type dopant diffusion may be realized without the need to create point defects in the drain region.

Further, while the preferred embodiment forms point defects in the silicon germanium layer prior to implantation of shallow source and drain extensions, point defects may be formed at other stages of processing prior to activation of the dopants, such as after implantation of shallow source and drain extensions, after spacer formation, or after implantation of deep source and drain regions. Accordingly, the location of the point defect creation process within the sequence of processes performed during MOSFET fabrication may be chosen in accordance the particular implementation. However, it is presently preferred to create point defects prior to implantation of the shallow source and drain extensions.

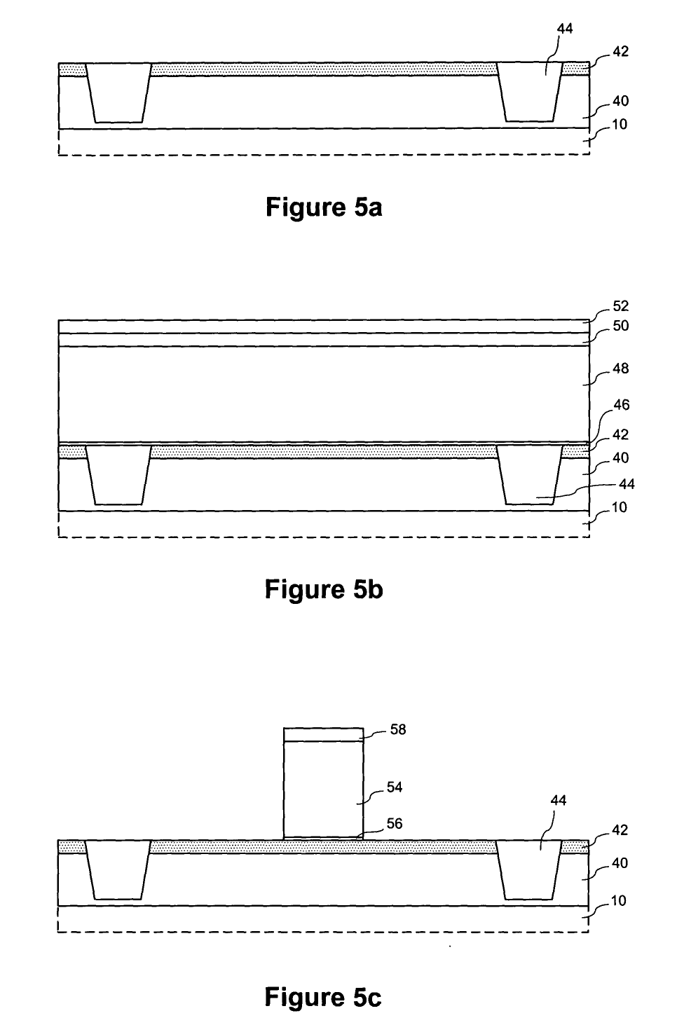

In addition, while the processing of FIGS. 5a-5i is specific to a strained silicon NMOS formed on a semiconductor substrate, analogous processing is applicable to NMOS devices formed on SOI substrates such as the device shown in FIG. 3.

Accordingly, a variety of embodiments may be implemented in accordance with the invention. In general terms, MOSFETs formed in accordance with embodiments of the invention are characterized by the formation during processing of an intermediate structure in which, prior to activation of n-type source and drain dopants, at least the source region contains a greater number of point defects than those formed by implantation of the n-type dopant itself.

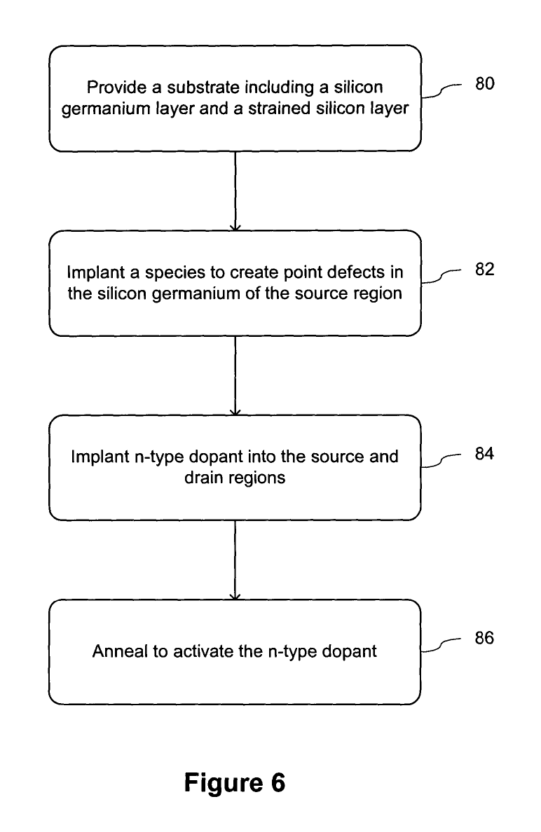

FIG. 6 shows a process flow for forming a semiconductor device that encompasses the preferred embodiment, the aforementioned alternatives and other alternatives. Initially a substrate is provided (80). The substrate includes a layer of silicon germanium on which is formed a layer of strained silicon. Point defects are then created in the silicon germanium layer in an NMOS device source region by implantation of a species (82). The point defects extend the duration of a transient region of n-type dopant diffusivity in the silicon germanium of the source region. N-type dopant is then implanted into the silicon germanium layer at source and drain regions of the NMOS device (84), and annealing is performed to activate the n-type dopant in the source and drain regions (86). The point defects retard n-type dopant diffusion during activation.

The tasks described in the above processes are not necessarily exclusive of other tasks, and further tasks may be incorporated into the above processes in accordance with the particular structures to be formed. For example, intermediate processing tasks such as formation and removal of passivation layers or protective layers between processing tasks, formation and removal of photoresist masks and other masking layers, doping and counter-doping, cleaning, planarization, and other tasks, may be performed along with the tasks specifically described above. Further, the processes described herein need not be performed on an entire substrate such as an entire wafer, but may instead be performed selectively on sections of the substrate. Also, while tasks performed during the fabrication of structure described herein are shown as occurring in a particular order for purposes of example, in some instances the tasks may be performed in alternative orders while still achieving the purpose of the process. Thus, while the embodiments illustrated in the figures and described above are presently preferred, it should be understood that these embodiments are offered by way of example only. The invention is not limited to a particular embodiment, but extends to various modifications, combinations, and permutations that fall within the scope of the claims and their equivalents.

1. A method for forming a semiconductor device, comprising:
providing a substrate comprising a layer of silicon germanium having formed thereon a layer of strained silicon;
implanting a species to create point defects in the silicon germanium layer at a source region of an NMOS device to extend the duration of a transient region of n-type dopant diffusivity in the silicon germanium of the source region;
implanting n-type dopant into the silicon germanium layer to form source and drain regions of the NMOS device; and
annealing to activate the n-type dopant in the source and drain regions of the NMOS device, wherein said point defects retard n-type dopant diffusion during said activation.

2. The method claimed in claim 1, wherein creating said point defects is performed prior to implanting shallow source and drain extensions of the NMOS device.

3. The method claimed in claim 1, wherein creating said point defects is performed subsequent to implanting shallow source and drain extensions of the NMOS device and prior to forming a spacer around a gate of the NMOS device.

4. The method claimed in claim 1, wherein creating said point defects is performed subsequent to forming a spacer around a gate of the NMOS device and prior to implanting deep source and drain regions of the NMOS device.

5. The method claimed in claim 1, wherein creating said point defects is performed subsequent to forming a spacer around a gate of the NMOS device and prior to implanting deep source and drain regions of the NMOS device.

6. The method claimed in claim 1, wherein creating said point defects is performed subsequent to implanting deep source and drain regions of the NMOS device.

7. The method claimed in claim 1, wherein creating said point defects is performed prior to implanting said n-type dopant.

8. The method claimed in claim 1, wherein creating said point defects is performed after implanting said n-type dopant.

9. The method claimed in claim 1, wherein creating said point defects comprises selectively masking the substrate to protect an active region of a PMOS device on the substrate and to protect a drain region of the NMOS device.

10. The method claimed in claim 1, wherein said species is also implanted into the silicon germanium layer in a drain region of the NMOS device to extend the duration of a transient region of n-type dopant diffusivity in the silicon germanium of the drain region.

11. The method claimed in claim 10, wherein creating said point defects comprises selectively masking the substrate to protect an active region of a PMOS device on the substrate.

12. The method claimed in claim 1, wherein the species implanted to create point defects is germanium.

13. The method claimed in claim 1, wherein the species implanted to create point defects is silicon.

14. The method claimed in claim 1, wherein the species implanted to create point defects is an inert element.

15. The method claimed in claim 1, wherein the silicon germanium layer is formed on a silicon substrate.

16. The method claimed in claim 1, wherein the silicon germanium layer is formed on a dielectric layer.

17. The method claimed in claim 1, wherein said annealing is performed for a time that is less than the duration of the transient region of n-type dopant diffusivity in the silicon germanium of the source region having said point defects created therein.

18. The method claimed in claim 1, wherein said annealing comprises performing multiple anneals, each of said multiple anneals being performed for a time that is less than the duration of the transient region of n-type dopant diffusivity in the silicon germanium of the source region having said point defects created therein.

19. The method claimed in claim 1, wherein the NMOS device includes strained silicon of the strained silicon layer in a channel region.

20. A method of forming an NMOS device, comprising:
forming a structure comprising n-type source and drain regions implanted in a silicon germanium layer of a substrate, wherein the silicon germanium of at least the source region contains point defects created by implantation of a species other than an n-type dopant; and
annealing to activate the source and drain regions, wherein said point defects retard n-type dopant diffusion during said activation.
